(19) United States
(12) Patent Application Publication
(10) Pub. No.: US 2024/0079319 A1
(43) Pub. Date: Mar. 7, 2024

(54) ELECTRONIC FUSE DEVICES AND INTEGRATION METHODS

(71) Applicant: GlobalFoundries Singapore Pte. Ltd., Singapore (SG)

(72) Inventors: SHU HUI LEE, Singapore (SG); JUAN BOON TAN, Singapore (SG); JIANXUN SUN, Singapore (SG); HARI BALAN, Singapore (SG); MYO AUNG MAUNG, Singapore (SG)

(21) Appl. No.: 17/930,410

(22) Filed: Sep. 7, 2022

(51) Int. Cl. H01L 23/525

(52) U.S. Cl. CPC H01L 23/5256

(57) ABSTRACT

An eFuse structure is provided, the structure comprising a first fuse link having a first side. The first fuse link having a first indentation on the first side, the first indentation having a non-linear profile. A first dummy structure may be laterally spaced from the first indentation of the first fuse link.

### FIELD OF THE INVENTION

The disclosed embodiments relate generally to electronic fuse devices, and more particularly, to structures and integration methods of electronic fuse devices.

### BACKGROUND

Electronic fuses (eFuses) are integrated circuits that can be used in place of conventional fuses within an electronic device. Electronic fuses can be used for detecting and reacting to overcurrent and overvoltage conditions. In some cases, eFuses may be used to reprogram integrated circuit chips. For example, if a sub-system in the chip is not behaving or responding in an expected manner, an eFuse can be blown to disconnect the sub-system or to switch in a back-up system.

It is desirable to improve an efficiency of the array of eFuse cells. An eFuse cell that is not efficient needs a higher programing current, which leads to an undesirable increase in chip power consumption. A chip may be provided with an array of eFuse cells which may be arranged in a back end of line layer, for example, metal 2 layer of the chip. It is challenging to reduce the eFuse size due to constraints on metal line dimensions and spacing. Thereby, there is a need for an improved eFuse structure to overcome the challenges mentioned above.

### SUMMARY

In an aspect of the present disclosure, an eFuse structure is provided, the structure comprising a first fuse link having a first side and a second side opposite to the first side. The first fuse link having a first indentation on the first side, wherein the first indentation has a non-linear profile. A first dummy structure may be laterally spaced from the first indentation of the first fuse link.

In another aspect of the present disclosure, an eFuse structure is provided, the structure comprising a first fuse link having a first side and a second side opposite to the first side. The first fuse link having a first indentation on the first side, wherein the first indentation has a non-linear profile. A first dummy structure may be laterally spaced from the first indentation of the first fuse link. A top surface of the first dummy structure may be co-planar with a top surface of the first fuse link.

In yet another aspect of the present disclosure, a method of fabricating an eFuse structure is provided, the method comprising forming a first fuse link having a first side and a second side opposite to the first side, whereby the first fuse link includes a first indentation on the first side and the first indentation has a non-linear profile. The method further comprises forming of a first dummy structure may be formed laterally spaced from the first indentation of the first fuse link.

### BRIEF DESCRIPTION OF THE DRAWINGS

The disclosed embodiments will be better understood from a reading of the following detailed description, taken in conjunction with the accompanying drawings:

FIG. 1A shows a top-down view of an eFuse structure, according to an embodiment of the disclosure.

FIG. 1B shows a corresponding cross-sectional view of the eFuse structure shown in FIG. 1A taken along section line X-X′, according to an embodiment of the disclosure.

FIG. 1C shows a corresponding cross-sectional view of the eFuse structure shown in FIG. 1A taken along section line Y-Y′, according to an embodiment of the disclosure.

FIG. 1D shows a corresponding cross-sectional view of the eFuse structure shown in FIG. 1A taken along section line X-X′, according to another embodiment of the disclosure.

FIG. 1E shows a corresponding cross-sectional view of the eFuse structure shown in FIG. 1A taken along section line Y-Y′, according to another embodiment of the disclosure.

FIG. 2 shows a top-down view of an eFuse structure, according to another embodiment of the disclosure.

FIG. 3 shows a top-down view of an eFuse structure, according to yet another embodiment of the disclosure.

FIG. 4 shows a top-down view of an eFuse structure, according to yet another embodiment of the disclosure.

FIGS. 5A and 5B, and 6 show a fabrication process flow for the eFuse structure shown in FIGS. 1A to 1C, according to some embodiments of the disclosure.

For simplicity and clarity of illustration, the drawings illustrate the general manner of construction, and certain descriptions and details of well-known features and techniques may be omitted to avoid unnecessarily obscuring the discussion of the described embodiments of the devices. Additionally, elements in the drawings are not necessarily drawn to scale. For example, the dimensions of some of the elements in the drawings may be exaggerated relative to other elements to help improve understanding of embodiments of the devices. The same reference numerals in different drawings denote the same elements, while similar reference numerals may, but do not necessarily, denote similar elements.

### DETAILED DESCRIPTION

The following detailed description is exemplary in nature and is not intended to limit the devices or the application and uses of the devices. Furthermore, there is no intention to be bound by any theory presented in the preceding background of the devices or the following detailed description.

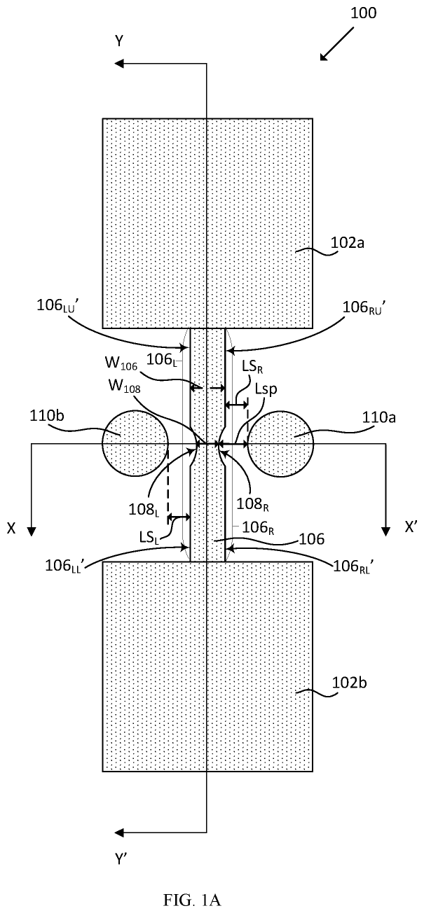

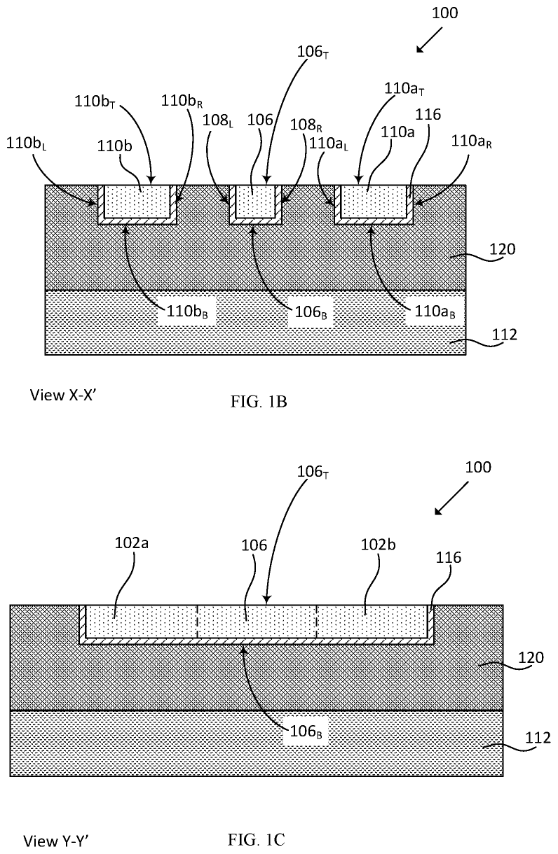

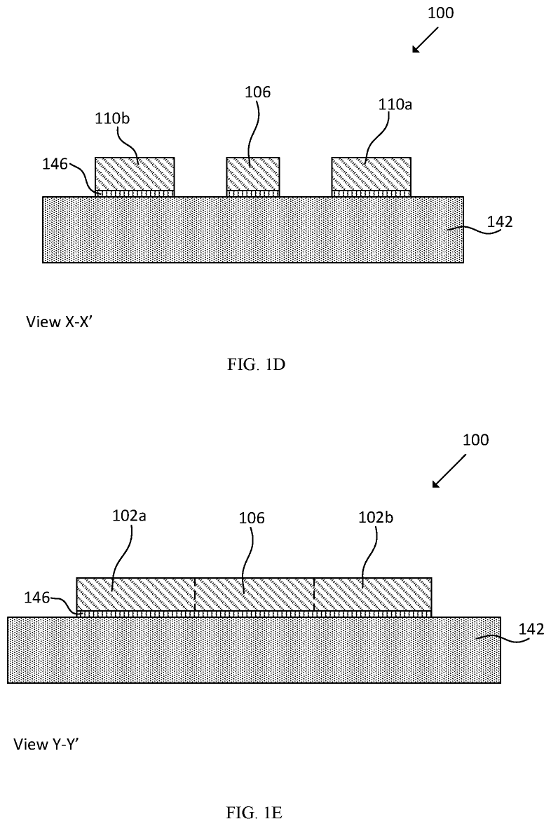

FIG. 1A shows a top-down view of an eFuse structure 100, according to an embodiment of the disclosure. The eFuse structure 100 may include a fuse link 106 arranged between and directly contacting the contacts 102a and 102b. The fuse link 106 and the contacts 102a and 102b may form a continuous structure. In an embodiment, the fuse link 106 may have a smaller width than the contacts 102a and 102b. The fuse link 106 may have a first side 106_{R} and a second side 106_{L} opposite to the first side 106_{R}. A first indentation 1088 may be on the first side 106_{R}. A second indentation 108_{L} may be on the second side 106_{L}. In an embodiment, the first indentation 1088 may be arranged directly opposite to the second indentation 108_{L} on the fuse link 106. In another embodiment, the first indentation 1088 may be diagonally spaced from the second 108_{L} indentation. For example, the first indentation 1088 may be arranged closer to the first contact 102a than the second contact 102b while the second indentation 108_{L} may be arranged closer to the second contact 102b than the first contact 102a.

A first dummy structure 110a may be adjacent to and laterally spaced from the first indentation 1088. A second dummy structure 110b may be adjacent to and laterally spaced from the second indentation 108_{L}. The first and second dummy structures may be arranged between and spaced from the contacts 102a and 102b. Each of the dummy structures, 110a and 110b, may be electrically isolated from other terminals, for example, the contacts 102a and 102b and the fuse link 106.

In an embodiment, the first and second dummy structures, 110a and 110b, may each have a circular shape. In other embodiments, the dummy structures may each have an elliptical or polygonal shape. In an embodiment, the first and second dummy structures may have the same size. In another embodiment, the first and second dummy structures may have different sizes. For example, the first dummy structure 110a may be larger than the second dummy structure 110b.

As shown in FIG. 1A, the fuse link 106 may have a non-linear section between two linear portions. The non-linear section may include the first indentation 1088 on a first side 106_{R} and the second indentation 108_{L} on the second side 106_{L}, where each of the first and second indentations each have a non-linear profile, for example, a curved profile. In another embodiment, the indentations may each have an angular or notched profile. The linear portions may include upper linear portions 106_{RU}′ and 106_{LU}′, and lower linear portions 106_{RL}′ and 106_{LL}′ of the fuse link 106. Each of the indentations may be arranged between an upper linear portion and a lower linear portion of the fuse link 106. For example, the first indentation 1088 may be arranged between upper linear portion 106_{RU′} and lower linear portion 106_{RL′}. In an embodiment, the first and second indentations, 108_{R} and 108_{L}, may each have a profile matching the shape of the adjacent dummy structure. For example, the first indentation 108_{R} may have a curved profile to match the adjacent first dummy structure 110a which may have a circular shape. A width W₁₀₈ of a non-linear section of the fuse link 106 may be measured from a point on the first indentation 108_{R} to an opposite point on the second side 106_{L}. In an embodiment, the width W₁₀₈ may be measured from the mid-point of the first indentation 108R to an opposite point on the second side 106_{L}. In another embodiment, the width W₁₀₈ may be measured from the mid-point of the first indentation 108_{R} to the mid-point of the second indentation 108_{L}. A width W₁₀₆ of a linear section of the fuse link 106 may be measured from a point on one side of the linear portion, for example, a point on the upper linear portion 106_{RU}′, to an opposite point on the other side of the linear portion, for example, a point on the upper linear portion 106_{LU}′. In an embodiment, the width W₁₀₈ may be narrower than the width W₁₀₆ of the fuse link 106, for example, the width W₁₀₈ may be at least ten percent narrower than the width W₁₀₆.

Still referring to FIG. 1A, a lateral spacing measured from a linear portion of the fuse link 106 to a parallel line extrapolated from the side surface of the dummy structure adjacent to the fuse link 106. For example, lateral spacing LS_{R} may be measured from the upper linear portion 106_{RU}′ to a parallel line extrapolated from the side surface of the first dummy structure 110a. Similarly, a lateral spacing LS_{L} may be measured from the lower linear portion 106_{LL}′ to a parallel line extrapolated from the side surface of the second dummy structure 110b. In an embodiment, the lateral spacing may not be smaller than the design rule minimum spacing, for example, the lateral spacing may at least be equal to the design rule minimum spacing. The term “design rule minimum spacing” may refer to a minimum separation distance between two features for a given technology. In another embodiment, the lateral spacing may be larger than the design rule minimum spacing.

FIG. 1B shows a corresponding cross-sectional view of the eFuse structure 100 shown in FIG. 1A taken along section line X-X′, according to an embodiment of the disclosure. The fuse link 106, and first 110a and second 110b dummy structures may be arranged in a dielectric layer 120 and there may be another dielectric layer 112 below the dielectric layer 120. A first portion of the dielectric layer 120 may be arranged between the fuse link 106 and the first dummy structure 110a, electrically insulating the fuse link 106 from the first dummy structure 110a. For example, a portion of dielectric layer 120 may be between the first indentation 1088 and the side surface 110a_{L} of the first dummy structure 110a. A second portion of the dielectric layer 120 may be arranged between the fuse link 106 and the second dummy structure 110b, electrically insulating the fuse link 106 from the second dummy structure 110b. For example, a portion of dielectric layer 120 may be between the second indentation 108_{L} and the side surface 110b_{R} of the second dummy structure 110b. In some embodiments, the top surfaces of the fuse link 106, first and second dummy structures may be substantially co-planar. For example, the top surface 106_{T} of the fuse link 106, the top surface 110a_{T} of the first dummy structure 110a and the top surface 110b_{T} of the second dummy structure 110b may be substantially co-planar. In an embodiment, the first dummy structure 110a, fuse link 106 and second dummy structure 110b may include a barrier liner 116. For example, the barrier liner 116 may directly contact the side surfaces 110a_{R} and 110a_{L}, and the bottom surface 110a_{B} of the first dummy structure 110a, as well as the side surfaces 110b_{R} and 110b_{L}, and the bottom surface 110b B of the second dummy structure 110b. The barrier liner may also directly contact the side and bottom surfaces of the fuse link 106, for example, the first 106_{L} and second 106_{R} sides, and the bottom surface 106E of the fuse link 106. In some embodiments, the barrier liner 116 may be absent.

FIG. 1C shows a corresponding cross-sectional view of the eFuse structure 100 shown in FIG. 1A taken along section line Y-Y′, according to an embodiment of the disclosure. The contacts 102a and 102b and the fuse link 106 may be arranged in the dielectric layer 120. In an embodiment, the top surface 106_{T} of the fuse link 106 may be substantially co-planar with top surfaces of the contacts 102a and 102b. The bottom surface 106E may be substantially co-planar with the bottom surfaces of the contacts 102a and 102b.

The dielectric layer 120 may be made of a suitable dielectric material, for example, silicon dioxide or any other suitable dielectric material. The dielectric layer 112 may be made of a suitable dielectric material, for example, carbon doped oxide dielectric comprised of Si, C, O and H (SiCOH), fluorine-doped tetraethyl orthosilicate, or any other suitable dielectric material. The barrier liner 116 may be made of a suitable metal, for example, tantalum nitride, titanium nitride, or any other suitable metals. The fuse link 106, contacts 102a and 102b, first 110a and second 110b dummy structures may be made of a suitable conductive material, for example, copper, metal silicides, aluminum, or any other suitable conductive material. In an embodiment, the fuse link 106, contacts 102a and 102b, and first 110a and second 110b dummy structures may be made of the same conductive material. In another embodiment, the fuse link 106, contacts 102a and 102b, and first 110a and second 110b dummy structures may be made of different conductive materials.

FIG. 1D shows a corresponding cross-sectional view of the eFuse structure 100 shown in FIG. 1A taken along section line X-X′, according to another embodiment of the disclosure. The fuse link 106, first and second dummy structures, 110a and 110b, may be arranged over a substrate 142. In an embodiment, a dielectric liner 146 may between the fuse link 106 and the substrate 142, spacing the fuse link 106 from the substrate 142. The dielectric liner 146 may also be between the dummy structures and the substrate 142, spacing the first and second dummy structures 110a and 110b, from the substrate 142. The fuse link 106, first and second dummy structures, 110a and 110b, may be made of a suitable conductive material, for example, polysilicon or any other suitable conductive material. The substrate 142 may be made of a suitable semiconductor substrate material, for example, silicon or any other suitable semiconductor material. The dielectric liner 146 may be made of a suitable dielectric material, for example, silicon dioxide or any other suitable dielectric material.

FIG. 1E shows a corresponding cross-sectional view of the eFuse structure 100 shown in FIG. 1A taken along section line Y-Y′, according to another embodiment of the disclosure. The dielectric liner 146 may be arranged directly on the substrate 142, and directly below contacts 102a, 102b, and fuse link 106.

During the eFuse structure 100 operation, a voltage may be applied to the contact 102a while the contact 102b may be grounded. A current may flow through the fuse link 106. The non-linear section of the fuse link 106 has a narrower width W₁₀₈ and consequently, a higher resistance to the current flow, which may cause localized heating leading to at least one part of the fuse link 106 breaking down, resulting in a blown fuse. The breaking down of the fuse link 106 may result in debris from broken fuse link being ejected from the fuse link region and being deposited on the surrounding features in the vicinity, which may interfere with the device operation and thus is undesirable. The first 110a and second 110b dummy structures adjacent to the fuse link may help to block the debris and prevent the debris from reaching and being deposited on the surrounding features as aforementioned.

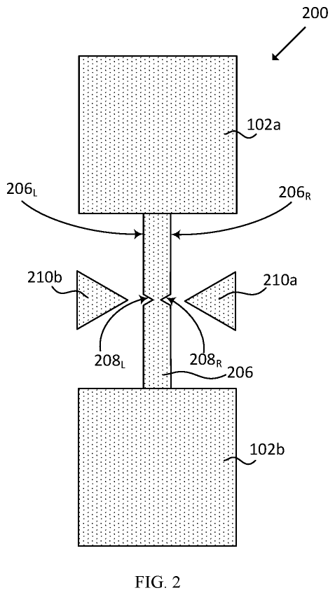

FIG. 2 shows a top-down view of an eFuse structure 200, according to another embodiment of the disclosure. Like numerals in FIG. 2 may refer to like features in FIG. 1A. The eFuse structure 200 may have features similar to the eFuse structure 100, but the eFuse structure 200 may include a fuse link 206 having first 208_{R} and second 208_{L} indentations that may have an angular profile. For example, each of the indentations 208_{R} and 208_{L} may have two linear edges that meet in a corner. The fuse link 206 has a first side 206_{R} and a second side 206_{L} arranged opposite to the first side 206_{R}. The first indentation 208_{R} may be on the first side 206_{R}. The second indentation 208_{L} may be on the second side 206_{L}. In an embodiment, the first indentation 208_{R} may be arranged opposite to the second indentation 208_{L}. For example, the corner of the first indentation 208_{R} may be arranged directly opposite to the corner of the second indentation 208_{L} leading to a reduced width of the fuse link 106 measured between the corners of the first 208_{R} and second 208_{L} indentations. In another embodiment, the first indentation 208_{R} may be diagonally spaced from the second indentation 208_{L}. For example, the first indentation 208_{R} may be arranged next closer to the first contact 102a than the second contact 102b while the second indentation 208_{L} may be arranged closer to the second contact 102b than the first contact 102a. In an embodiment, the first and second dummy structures, 210a and 210b, may each have a polygonal shape, for example, a triangular shape having 3 corners. In an embodiment, a corner of the first dummy structure 210a may be laterally spaced from the first indentation 208_{R}. In an embodiment, a corner of the second dummy structure 210b may be laterally spaced from the second indentation 208_{L}.

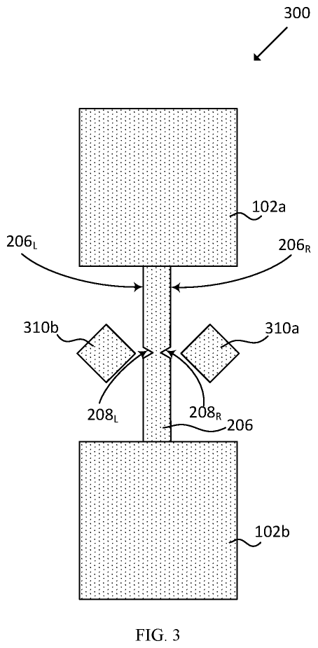

FIG. 3 shows a top-down view of an eFuse structure 300, according to yet another embodiment of the disclosure. Like numerals in FIG. 3 may refer to like features in FIG. 2. The eFuse structure 300 has similar features to the eFuse structure 200 but may include first and second dummy structures, 310a and 310b, each having a polygonal shape having 4 corners, for example, a quadrilateral shape having 4 corners. A corner of the first dummy structure 310a may be laterally spaced from the first indentation 208_{R}, while a corner of the second dummy structure 310b may be laterally spaced from the second indentation 208_{L}. In an embodiment, the dummy structures may each have a square shape. In another embodiment, the dummy structures may each have a quadrilateral shape having unequal sides. In yet another embodiment, the first and second dummy structures, 310a and 310b, may each have different shapes. For example, the first dummy structure 310a may have a quadrilateral shape having sides with different lengths and the second dummy structure 310b may have a square shape.

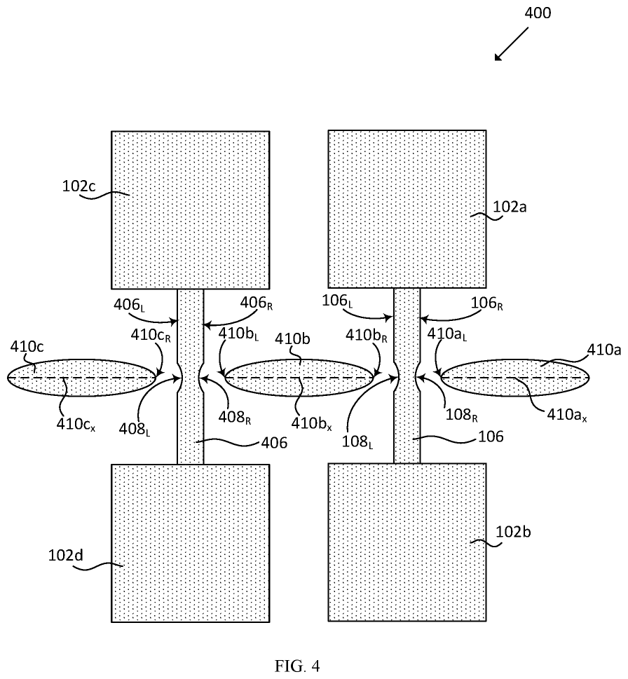

FIG. 4 shows a top-down view of an eFuse structure 400, according to yet another embodiment of the disclosure. Like numerals in FIG. 4 may refer to like features in FIG. 1A. The eFuse structure 400 may have features similar to that of eFuse structure 100 but may include an additional set of contacts 102c and 102d which may be laterally spaced from contacts 102a and 102b respectively, and a second fuse link 406 connecting the contacts 102c and 102d, where the second fuse link 406 may be adjacent to and spaced from the first fuse link 106. The eFuse structure 400 may further include dummy structures each having an elliptical shape, for example, dummy structures having an oval-shape. In an embodiment, a first dummy structure 410a may be adjacent to and spaced from fuse link 106, a second dummy structure 410b may be between and spaced from fuse links 106 and 406, and a third dummy structure 410c may be adjacent to and spaced from fuse link 406.

The second fuse link 406 may be electrically isolated from the first fuse link 106. The second fuse link 406 may have a first side 406_{R} and a second side 406_{L} arranged opposite to the first side 406_{R}. The first 406_{R} and second 406_{L} sides may each have an indentation, for example, the first side 406_{R} may include a first indentation 408_{R} while the second side 406_{L} may include a second indentation 408_{L}. The first 408_{R} and second 408_{L} indentations may each have a curved profile.

Each of the dummy structures 410a, 410b and 410c may have vertices where a long axis intersects the oval. A long axis 410aₓ of the first dummy structure 410a is shown as a dashed line and a vertex 410a_{L} has been labelled accordingly. In an embodiment, the vertex 410a_{L} of the first dummy structure 410a may be laterally spaced from the first indentation 108_{R} of the first fuse link 106. A vertex 410b_{R} of the second dummy structure 410b may be laterally spaced from the second indentation 108_{L} of the first fuse link 106. The second dummy structure 410b may also include a vertex 410b_{L} arranged opposite to the vertex 410b_{R}. The vertex 410b_{L} of the second dummy structure 410b may be laterally spaced from the first indentation 408_{R} of the second fuse link 406. The third dummy structure 410c may be spaced from the second side 406_{L} of the second fuse link 406. A vertex 410c_{R} of the third dummy structure 410c may be laterally spaced from the second indentation 408_{L}.

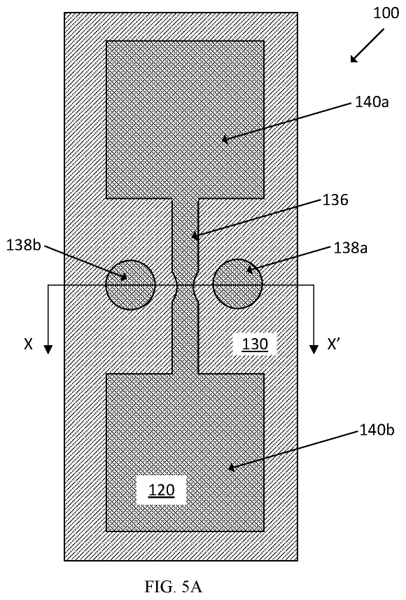

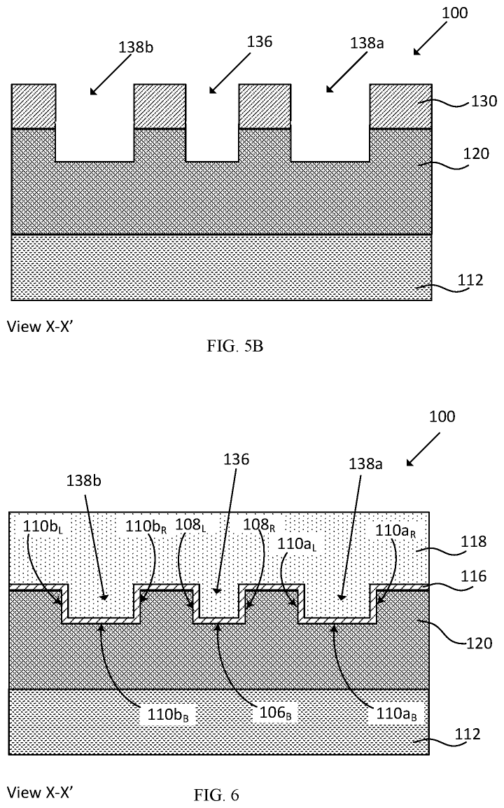

FIGS. 5A and 5B, and 6 show a fabrication process flow for the eFuse structure 100 shown in FIGS. 1A to 1C, according to some embodiments of the disclosure. FIG. 5A shows a top-down view of the eFuse structure 100 at an exemplary processing step, for example, after an etching process has been performed to form openings in the dielectric layer 120 for the contacts 102a and 102b, fuse link 106 and first 110a and second 110b dummy structures. The contact openings 140a and 140b, fuse opening 136 and dummy openings 138a and 138b may be formed with the help of a patterned photoresist layer 130. The contact openings 140a and 140b and the fuse opening 136 may be connected to each other, while the dummy openings 138a and 138b may be isolated from the contact openings 140a and 140b and the fuse opening 136. The patterned photoresist layer 130 may be formed by a photolithography process with the help of a photolithography mask having a mask design in which the lateral spacings LS_{R} and LS_{L}, shown in FIG. 1A, are not smaller than the design rule minimum spacing, for example, lateral spacings LS_{R} and LS_{L} are at least equal to the design rule minimum spacing for the corresponding technology node, thus resulting in the formation of indentations on the fuse link due to the optical proximity effect. The optical proximity effect may refer to the producing a distorted pattern as compared to the original design, which may be due to ray diffraction unintendedly exposing portions of the photoresist during photolithography patterning of features that are close together.

FIG. 5B shows a corresponding cross-sectional view of the eFuse structure 100 shown in FIG. 5A taken along section line X-X′, in accordance with some embodiments of the disclosure. The dielectric layer 112 may be deposited over a substrate (not shown), another dielectric layer, or a metal layer. The formation of the dielectric layer 112 may include depositing a layer of a suitable dielectric material, for example, carbon doped oxide dielectric comprised of Si, C, O and H (SiCOH), fluorine-doped tetraethyl orthosilicate, or any other suitable dielectric material. A dielectric layer 120 may be deposited over a top surface of the dielectric layer 112. The formation of the dielectric layer 120 may include depositing a layer of a suitable dielectric material, for example, silicon dioxide, or any other suitable dielectric material. The dielectric layer 120 may have a lower etching rate than the dielectric layer 112. The deposition processes for the dielectric layer 112 and the dielectric layer 120 may be by chemical vapor deposition, physical vapor deposition or any other suitable deposition processes. A photoresist layer may be deposited on a top surface of the dielectric layer 120 and may subsequently be exposed to a suitable light through a photolithography mask layer as part of a photolithography process and subsequently developed to form patterned photoresist layer 130 having openings corresponding to the desired positions of the fuse link 106, the first 110a and second 110b dummy structures, and the contacts 102a and 102b (not shown). The fuse opening 136 may be arranged between the first 138a and second 138b dummy openings. The fuse opening 136, first dummy 138a and second dummy 138b openings may be formed in the dielectric layer 120 by a material removal process. A wet etch or dry etch process may be used to remove the exposed portions of the dielectric layer 120. The etching process may leave behind another portion of the dielectric layer 120 under the patterned photoresist layer 130.

The eFuse structures 200, 300 and 400 shown in FIGS. 2, 3 and 4, respectively, may be fabricated using a mask layer with different patterns as compared to the eFuse structure 100.

FIG. 6 shows a corresponding cross-sectional view of the eFuse structure 100 at a subsequent processing step. The patterned photoresist layer 130 may be removed to expose the dielectric layer 120 and a barrier liner material 116 may be deposited on the side surfaces and bottom surface 106E of the fuse opening 136. The barrier liner material 116 may also be deposited on the side surfaces 110a_{R} and 110a_{L}, and the bottom surface 110a_{B} of the first dummy opening 138a. The barrier liner material 116 may also be deposited on the side surfaces 110b_{R} and 110b_{L}, and the bottom surface 110b_{B} of the second dummy opening 138b. Although not shown, it is understood that the barrier liner material 116 may also be deposited on the side surfaces and bottom surface of the openings for contacts 102a and 102b. The barrier liner material 116 may be formed by depositing a layer of a suitable metal, for example, tantalum nitride, titanium nitride, or any other suitable metals. A conductive layer 118 may be deposited on a top surface of the barrier liner material 116, filling up the fuse opening 136, and first 138a and second 138b dummy openings, and openings for contacts 102a and 102b (not shown). The formation of the conductive layer 118 may include depositing a layer of a suitable conductive material, for example, copper, metal silicides, aluminum, or any other suitable conductive material. The conductive layer 118 and the barrier liner material 116 may be deposited by a suitable deposition process, for example, atomic layer deposition, electroplating, physical vapor deposition or any other suitable deposition processes.

The fabrication process may continue to form the eFuse structure 100 shown in FIG. 1B. To form the eFuse structure 100 shown in FIG. 1B, a suitable planarization process, for example, chemical mechanical planarization may be used to remove a portion of a conductive stack, including the conductive layer 118 and the barrier liner material 116 from the top surface of the dielectric layer 120. The planarization process may leave behind a first portion of the conductive stack in the fuse opening 136 to form the fuse link 106. The planarization process may also leave behind a second and third portions of the conductive stack in the first dummy 138a and second dummy 138b openings, respectively to form the dummy structures 110a and 110b, respectively. Although not shown for simplicity, the contacts 102a and 102b may also be formed together with the fuse link 106 and first 110a and second 110b dummy structures.

According to another embodiment of the disclosure, the process for forming the eFuse structure 100 shown in FIG. 1D will now be described. A substrate 142 may be provided and dielectric liner 146 may be formed over the substrate 142. The formation of the dielectric liner 146 may include depositing a layer of a suitable dielectric material, for example, silicon dioxide or any other suitable dielectric material. A suitable conductive material, for example, polysilicon or any other suitable conductive material may be deposited over the silicon dioxide layer to form a material stack comprising the dielectric liner 146 and the conductive material. A layer of photoresist may be deposited over the material stack and patterned to form suitable photoresist patterns as desired. For example, the photoresist patterns may cover the portions of the material stack intended to form the contacts 102a and 102b, fuse link 106 and the dummy structures 110a and 110b. A wet etch or dry etch process may be used to remove portions of the material stack not covered by the photoresist patterns, leaving behind portions of the material stack under the photoresist patterns to form the contacts, fuse link and dummy structures. The photoresist patterns may subsequently be removed.

The terms “first”, “second”, “third”, and the like in the description and in the claims, if any, are used for distinguishing between similar elements and not necessarily for describing a particular sequential or chronological order. It is to be understood that the terms so used are interchangeable under appropriate circumstances such that the embodiments of the device described herein are, for example, capable of operation in sequences other than those illustrated or otherwise described herein. The terms “left”, “right”, “front”, “back”, “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements but may include other elements not expressly listed or inherent to such process, method, article, or device.

While several exemplary embodiments have been presented in the above detailed description of the device, it should be appreciated that number of variations exist. It should further be appreciated that the embodiments are only examples, and are not intended to limit the scope, applicability, dimensions, or configuration of the devices in any way. Rather, the above detailed description will provide those skilled in the art with a convenient road map for implementing an exemplary embodiment of the devices, it being understood that various changes may be made in the function and arrangement of elements and method of fabrication described in an exemplary embodiment without departing from the scope of this disclosure as set forth in the appended claims.

What is claimed:

1. An eFuse structure comprising:
a first fuse link having a first side and a second side opposite to the first side, the first fuse link having a first indentation on the first side, wherein the first indentation has a non-linear profile; and
a first dummy structure laterally spaced from the first indentation of the first fuse link.

2. The eFuse structure of claim 1, further comprising:
a second indentation on the second side of the first fuse link.

3. The eFuse structure of claim 1, wherein the first side of the fuse link comprises two linear portions and the first indentation is arranged between the two linear portions.

4. The eFuse structure of claim 2, wherein the first indentation is arranged opposite to the second indentation.

5. The eFuse structure of claim 2, further comprising:
a second dummy structure laterally spaced from the second indentation of the first fuse link.

6. The eFuse structure of claim 2, wherein the first indentation of the first fuse link and the second indentation of the first fuse link each has a curved profile.

7. The eFuse structure of claim 2, wherein the first dummy structure has a shape and the non-linear profile of the first indentation matches the shape of the first dummy structure.

8. The eFuse structure of claim 2, wherein the first indentation of the first fuse link and the second indentation of the first fuse link each has an angular profile.

9. The eFuse structure of claim 5, wherein the first dummy structure and the second dummy structure each have at least three corners, wherein a corner of the first dummy structure is laterally spaced from the first indentation of the first fuse link and a corner of the second dummy structure is laterally spaced from the second indentation of the first fuse link.

10. The eFuse structure of claim 5, wherein the first dummy structure and the second dummy structure each have a polygonal shape, a corner of the first dummy structure is laterally spaced from the first indentation of the first fuse link and a corner of the second dummy structure is laterally spaced from the second indentation of the first fuse link.

11. The eFuse structure of claim 5, wherein the first dummy structure and the second dummy structure each have an elliptical shape having a first vertex and a second vertex opposite to the first vertex, wherein the first vertex is laterally spaced from the first indentation of the first fuse link and the second vertex is laterally spaced from the second indentation of the first fuse link.

12. The eFuse structure of claim 5, wherein the first dummy structure and the second dummy structure are circular.

13. The eFuse structure of claim 5, wherein the first dummy structure has a different shape from the second dummy structure.

14. The eFuse structure of claim 1, wherein the first side of the first fuse link has a linear portion and a lateral spacing between the first dummy structure and the linear portion is not smaller than a design rule minimum spacing for a corresponding technology node.

15. The eFuse structure of claim 2, wherein the first side of the first fuse link has a first linear portion and the second side of the first fuse link has a second linear portion that is opposite to the first linear portion, and a first width between the first indentation and the second indentation of the first fuse link is at least ten percent narrower than a second width between the first linear portion and the second linear portion.

16. An eFuse structure comprising:
a first fuse link having a first side and a second side opposite to the first side, the first fuse link having a first indentation on the first side, wherein the first indentation has a non-linear profile; and
a first dummy structure laterally spaced from the first indentation of the first fuse link, wherein a top surface of the first dummy structure is co-planar with a top surface of the first fuse link.

17. The eFuse structure of claim 16, wherein the first side comprises two linear portions and the first indentation is arranged between the two linear portions.

18. The eFuse structure of claim 17, further comprising:
a second indentation on the second side of the first fuse link, and a second dummy structure laterally spaced from the second indentation of the first fuse link,
wherein a top surface of the second dummy structure is co-planar with the top surface of the first fuse link.

19. The eFuse structure of claim 16, wherein the first dummy structure has a shape and the non-linear profile of the first indentation matches the shape of the first dummy structure.

20. A method of fabricating an eFuse structure comprising:
forming a first fuse link having a first side and a second side opposite to the first side, wherein the first fuse link has a first indentation on the first side and the first indentation has a non-linear profile; and
forming a first dummy structure laterally spaced from the first indentation of the first fuse link.
